(19) United States
(12) Patent Application Publication
(10) Pub. No.: US 2026/0269561 A1
(43) Pub. Date: Sep. 10, 2026

(54) LASER MODULE, OPTICAL ENGINE, AND XR GLASSES

(71) Applicant: TDK Corporation, Tokyo (JP)

(72) Inventor: Yusuke SHIGETA, Tokyo (JP)

(73) Assignee: TDK Corporation, Tokyo (JP)

(21) Appl. No.: 19/557,477

(22) Filed: Mar. 5, 2026

(30) Foreign Application Priority Data
Mar. 7, 2025 (JP) 2025-036079

(51) Int. Cl. H01S 5/024; G02B 6/42; G02B 27/01; H01S 5/02235; H01S 5/0237; H01S 5/40

(52) U.S. Cl. CPC H01S 5/02469; G02B 6/42; G02B 6/4202; G02B 27/0172; H01S 5/02235; H01S 5/0237; H01S 5/4093; G02B 2027/0178

(57) ABSTRACT

The laser module comprises a plurality of subcarriers 20, a plurality of laser elements 30 mounted on the main surfaces of the plurality of subcarriers 20, an optical waveguide substrate 40 having an optical waveguide layer 50 on its main surface, which has an optical waveguide 51 for guiding laser light respectively emitted from the plurality of laser elements 30, a heat sink 60 having comb-shaped fin portion that contact both side surfaces of the plurality of subcarriers 20, and a package 110 that houses the plurality of subcarriers 20 on which the plurality of laser elements 30 are mounted, the optical waveguide substrate 40 on which the optical waveguide layer 50 is mounted, and the heat sink 60. The plurality of subcarriers 20 are thermally coupled to the package 110 via the heat sink 60.

### CROSS-REFERENCE TO RELATED APPLICATION

This application claims a priority, under the Paris Convention, to Japanese Patent Application No. 2025-036079 filed on Mar. 7, 2025, the entirety of which is incorporated herein by reference.

### TECHNICAL FIELD

The present disclosure relates to a laser module, an optical engine, and XR glasses.

### BACKGROUND

XR glasses, such as AR (Augmented Reality) glasses and VR (Virtual Reality) glasses, are expected to be small wearable devices. The key to popularizing wearable devices such as AR glasses and VR glasses is to miniaturize them so that each function fits into the size of a normal pair of glasses.

International Publication No. WO 2021/149450 discloses an integrated optical device that is miniaturized by bonding a base that holds a laser element and a substrate on which an optical waveguide is provided on the surface with the light emission position of the laser element and the position of the optical waveguide precisely aligned via a metal layer.

FIG. 13 is a schematic plan view for explaining the integrated optical device disclosed in WO 2021/149450. FIG. 14 is a schematic cross-sectional view of the integrated optical device shown in FIG. 13 taken along line A-A'. The reference numerals in the figure correspond to the reference numerals of the components of the laser module of this embodiment, which will be described later, and only the components necessary for the explanation will be described here.

The integrated optical device shown in FIGS. 13 and 14 comprises a plurality of laser elements 30 (30-1, 30-2, 30-3), each of which is mounted on a main surface 21 (21-1, 21-2, 21-3), a plurality of individual subcarriers 20 (20-1, 20-2, 20-3) spaced apart from one another, an optical waveguide layer 50 having an optical waveguide 51 that guides the laser light emitted from the laser elements 30 (30-1, 30-2, 30-3), an optical waveguide substrate 40 on whose surface the optical waveguide layer 50 is provided, and a metal film 70 that bonds the subcarriers 20 (20-1, 20-2, 20-3) to the optical waveguide substrate 40.

As recognized by the present inventor, however, the integrated optical device disclosed in WO 2021/149450 has a structure in which the bottom surface of the subcarrier 20 is in contact with the package to dissipate heat generated by the laser element 30, but depending on the amount of heat generated by the laser element 30, sufficient heat dissipation may not be possible, thereby causing a concern that this structure may affect the optical characteristics of the laser element 30.

The present disclosure has been made to solve such conventional problems, and aims to provide a laser module, optical engine, and XR glasses that can efficiently dissipate heat generated by the laser element.

### Means for solving the problems

The present disclosure provides the following means to solve the above problems.

### SUMMARY

One aspect of the present disclosure provides a laser module includes a plurality of laser element bases, plurality of laser elements mounted on the respective main surfaces of the plurality of laser element bases, an optical waveguide substrate having an optical waveguide layer on its main surface that has an optical waveguide for guiding laser light emitted from the plurality of laser elements; a heat sink having comb-shaped fin portion in contact with both side surfaces of each of the plurality of laser element bases; and a package that houses the plurality of laser element bases on which the plurality of laser elements are mounted, the optical waveguide substrate on which the optical waveguide layer is provided, and the heat sink. The plurality of laser element bases are thermally coupled to the package via the heat sink.

One aspect of the present disclosure provides an optical engine comprising the laser module, and an optical scanning mirror that scans the light emitted from the laser module.

One aspect of the present disclosure provides an XR glasses comprising the optical engine.

### BRIEF DESCRIPTION OF DRAWINGS

FIG. 1 shows a schematic perspective view of a laser assembly provided in a laser module according to a first embodiment of the present disclosure.

FIG. 2 shows a schematic plan view of a laser assembly according to the first embodiment of the present disclosure.

FIG. 3 shows a schematic cross-sectional view of the laser assembly shown in FIG. 1 taken along line A-A'.

FIG. 4A shows a schematic perspective view of a laser element base.

FIG. 4B shows a schematic perspective view of an optical waveguide substrate.

FIG. 5A shows a schematic perspective view of a heat sink.

FIG. 5B shows a schematic perspective view of another example of a heat sink.

FIG. 6 shows a schematic plan view of a laser module according to the first embodiment of the present disclosure.

FIG. 7 shows a schematic cross-sectional view of the laser module shown in FIG. 6 taken along the X-Z plane.

FIG. 8 shows a plan view of the laser module shown in FIG. 6 with the cover removed.

FIG. 9 shows a schematic perspective view of a laser assembly provided in a laser module according to a second embodiment of the present disclosure.

FIG. 10 shows a plan view of the laser module according to the second embodiment of the present disclosure with the cover removed.

FIG. 11 shows a conceptual diagram for explaining XR glasses according to a third embodiment of the present disclosure.

FIG. 12 shows a conceptual diagram showing how an image is projected directly onto the retina by laser light emitted from a laser module according to an embodiment of the present disclosure.

FIG. 13 shows a schematic plan view of a portion of a conventional integrated optical device.

FIG. 14 shows a schematic cross-sectional view of the integrated optical device shown in FIG. 13 taken along line A-A'.

### DETAILED DESCRIPTION

One aspect of the present disclosure provides a laser module, an optical engine, and an XR glasses that can efficiently dissipate heat generated by a laser element.

Hereinafter, embodiments of the laser module, optical engine, and XR glasses according to the present disclosure will be described with reference to the drawings. Here, it should be noted that the dimensional ratios of the components in each drawing do not necessarily match the actual dimensional ratios.

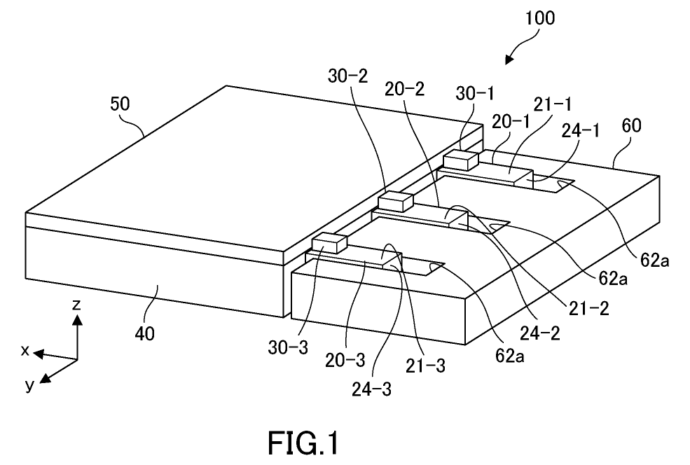

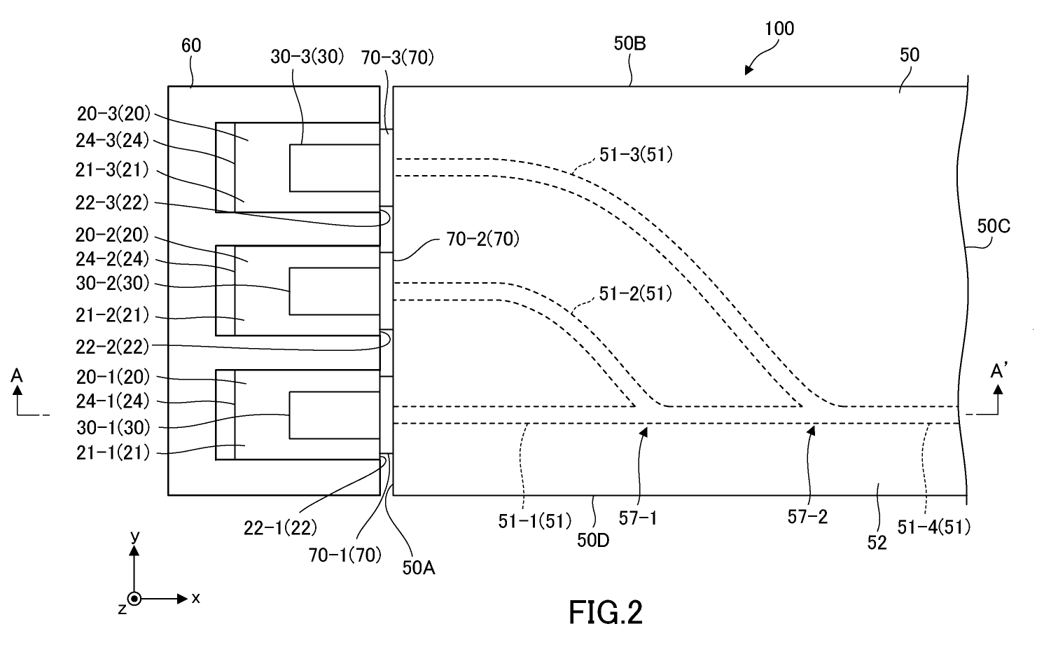

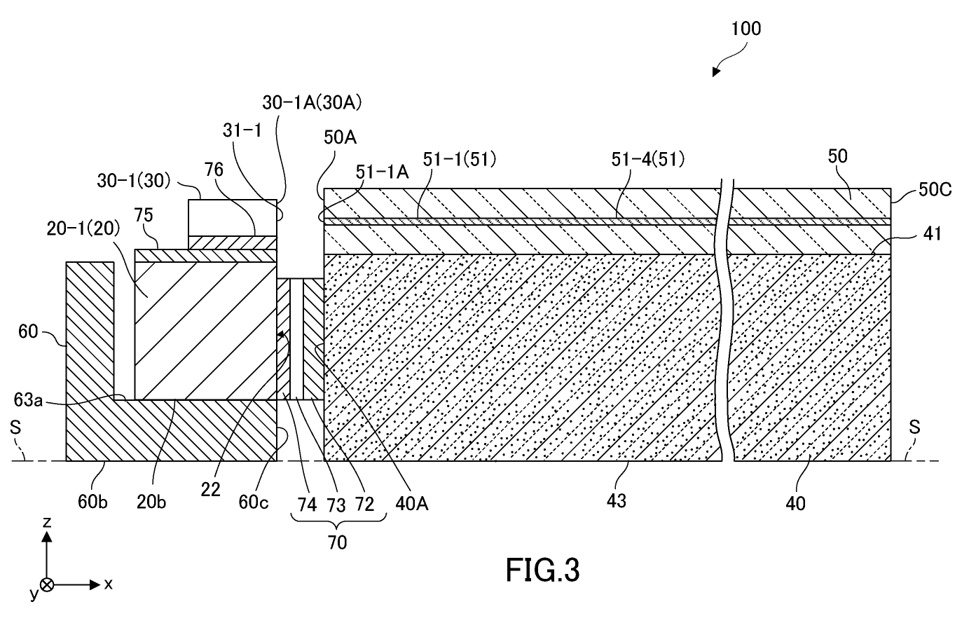

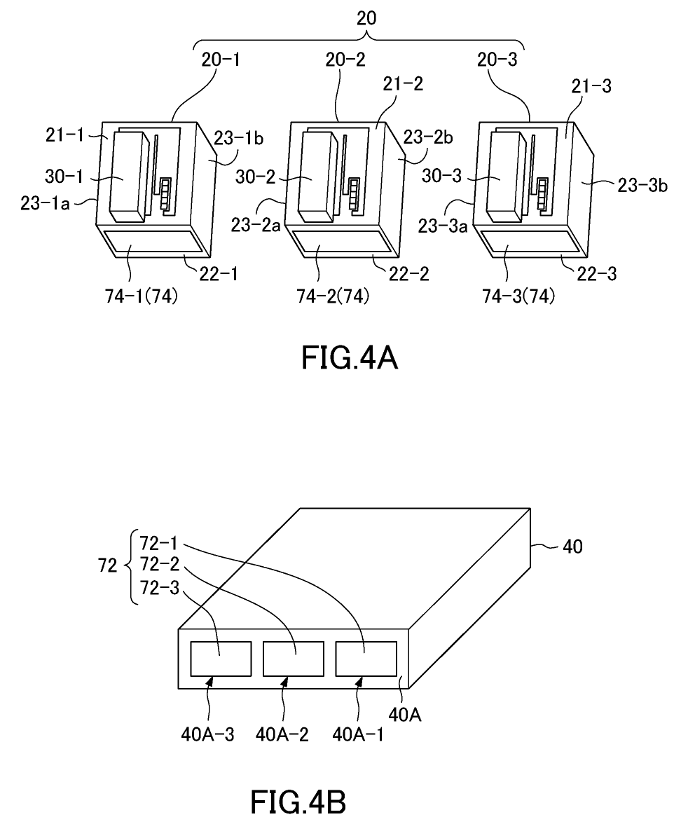

FIG. 1 is a schematic perspective view of a laser assembly provided in a laser module of the first embodiment. FIG. 2 is a schematic plan view of a portion of the laser assembly of this embodiment. FIG. 3 is a schematic cross-sectional view taken along line A-A' in the laser assembly shown in FIG. 2. FIG. 4A is a schematic perspective view of a laser element base, and FIG. 4B is a schematic perspective view of a substrate for optical waveguide.

The laser assembly 100 shown in FIGS. 1 to 3 comprises a plurality of laser element bases (hereinafter also referred to as "subcarriers") 20 (20-1, 20-2, 20-3), a plurality of laser elements 30 (30-1, 30-2, 30-3) mounted on the respective main surfaces 21 (21-1, 21-2, 21-3) of the plurality of subcarriers 20, an optical waveguide substrate 40, an optical waveguide layer 50 provided on the main surface 41 of the optical waveguide substrate 40, and a heat sink 60.

Various laser elements can be used as the laser element 30. For example, commercially available laser diodes (hereinafter also referred to as "LD") for red light, the green light, the blue light, near infrared light, ultraviolet light, etc. can be used. The red light (R) can be light having a peak wavelength of 630 nm or more and 830 nm or less, the green light (G) can be light having a peak wavelength of 500 nm or more and 550 nm or less, and the blue light (B) can be light having a peak wavelength of 380 nm or more and 500 nm or less. The near-infrared light can be light having a peak wavelength of 830 nm or more and 2000 nm or less.

In the laser assembly 100 shown in FIGS. 1 and 2, the laser elements 30-1, 30-2, and 30-3 will be described as LDs that emit blue laser light, LDs that emit green laser light, and LDs that emit red laser light, respectively, for the sake of convenience. The laser elements 30-1, 30-2, and 30-3 can be mounted on the individual subcarriers 20-1, 20-2, and 20-3, for example, as bare chips (unpackaged chips). Although the number of laser elements shown in FIGS. 1 and 2 is three, this is just an example and any number multiple can be used.

The subcarriers 20-1, 20-2, 20-3 have a rectangular parallelepiped shape and have a flat main surface 21 (21-1, 21-2, 21-3), a bonding surface 22 (22-1, 22-2, 22-3) that is a flat surface perpendicular to the main surface 21, side surfaces 23 (23-1a, 23-1b, 23-2a, 23-2b, 23-3a, 23-3b) that are flat surfaces perpendicular to the main surface 21 and the bonding surface 22, and end surfaces 24 (24-1, 24-2, 24-3) that are flat surfaces on the side opposite to the bonding surface 22.

The subcarriers 20-1, 20-2, and 20-3 are made of, for example, aluminum nitride (AlN), aluminum oxide (Al₂O₃), or silicon (Si).

Metal films 75 and 76 are provided between the subcarrier 20 and the laser element 30 (see FIG. 3). Each of the subcarriers 20 and each of the laser elements 30 are connected to each other via the respective metal films 75 and 76. The metal films 75 and 76 can be formed by any known method, but any known method such as sputtering, vapor deposition, or application of a metal paste can be used. The metal films 75 and 76 may contain one or more metals selected from the group consisting of gold (Au), platinum (Pt), silver (Ag), lead (Pb), indium (In), nickel (Ni), titanium (Ti) and tantalum (Ta), tungsten (W), an alloy of gold (Au) and tin (Sn), tin (Sn)-silver (Ag)-copper (Cu) solder alloy (SAC), SnCu, InBi, SnPdAg, SnBiIn, and PbBiIn, and may be made of one or more metals selected from this group.

The optical waveguide layer 50 has at least an optical waveguide that guides the laser light emitted from the laser element. There are no particular limitations on this optical waveguide layer, and any known configuration can be used. Hereinafter, examples of optical waveguide layers are shown.

The optical waveguide layer 50 has four end faces 50A, 50B, 50C, and 50D. The optical waveguide layer 50 shown in FIG. 2 is a rectangle with four 90° corners in a plan view (when viewed from the z direction), but is not limited to a rectangle with four 90° corners. Hereinafter, the end face 50A is also referred to as the incidence surface 50A, and the end face 50C is also referred to as the emission surface 50C.

The optical waveguide layer 50 is a layer that performs the function of a PLC (Planar Lightwave Circuit). The optical waveguides 51-1, 51-2, 51-3, and 51-4 correspond to the cores of an optical fiber.

The optical waveguide layer 50 is formed on the optical waveguide substrate 40, and as described above, the laser element 30 is mounted on the subcarrier 20.

The optical waveguide substrate 40 and the subcarrier 20 are integrated by eutectic bonding. This eutectic bonding allows for accurate optical axis positioning and also allows for miniaturization.

The optical waveguide substrate 40 is made of, for example, silicon (Si). The optical waveguide layer 50 is fabricated on the main surface 41 so as to be integrated with the optical waveguide substrate 40 by semiconductor processes including well-known photolithography and dry etching used in forming fine structures such as integrated circuits.

As shown in FIG. 2, the optical waveguide layer 50 is provided with optical waveguides 51-1, 51-2, and 51-3 in the same number as the laser elements 30-1, 30-2, and 30-3, an optical waveguide 51-4 where the optical waveguides 51-1, 51-2, and 51-3 join, and a cladding 52 surrounding the optical waveguides 51-1, 51-2, 51-3, and 51-4. There are no particular limitations on the thickness of the cladding 52 and the width direction dimension of the optical waveguides 51-1, 51-2, 51-3, and 51-4. For example, the optical waveguides 51-1, 51-2, 51-3, and 51-4 having a width direction dimension of about several microns are disposed in the cladding 52 having a thickness of about 50 μm.

The optical waveguides 51-1, 51-2, 51-3, 51-4 and the cladding 52 are made of, for example, a glass material (e.g., quartz glass). In this case, the optical waveguide layer 50 is sometimes called a quartz-based PLC. The refractive indexes of the optical waveguides 51-1, 51-2, 51-3, 51-4 are higher than the refractive index of the cladding 52 by a predetermined value. As a result, light incident on each of the optical waveguides 51-1, 51-2, 51-3, 51-4 propagates through each optical waveguide while being totally reflected at the interface between each optical waveguide and the cladding 52. The optical waveguides 51-1, 51-2, 51-3, 51-4 are doped with an impurity such as germanium (Ge) in an amount corresponding to the predetermined value mentioned above.

As shown in FIG. 2, the optical waveguides 51-1, 51-2, and 51-3 are gathered together just before reaching the emission surface 50C of the optical waveguide layer 50. That is, the optical waveguides 51-1, 51-2, and 51-3 merge sequentially as they move forward in the x-direction, and merge into one optical waveguide 51-4. The optical waveguide 51-4 reaches the emission surface 50C.

The optical waveguides and the corresponding laser elements are arranged in face-to-face relationship to each other with the optical axes precisely aligned so that the centers of the incidences of the optical waveguides 51-1, 51-2, and 51-3 of the optical waveguide layer 50 are almost aligned with the optical axes of the emitted light from the corresponding laser elements 30-1, 30-2, and 30-3 by performing the eutectic bonding between the optical waveguide substrate 40 and the subcarrier 20.

As shown in FIG. 3, the optical waveguide substrate 40 and the subcarrier 20 are arranged in such a manner that the incidence surface 50A of the optical waveguide layer 50 faces the emission surface 30A (30-1A) of the laser element 30. In detail, the emission port 31-1 of the laser element 30-1 faces the incidence port 51-1A of the optical waveguide 51-1. In the y and z directions, the optical axis of the blue light emitted from the laser element 30-1 and the center of the incidence port 51-1A approximately overlap. Similarly, the emission port of the laser element 30-2 faces the incidence port of the optical waveguide 51-2. In the y and z directions, the optical axis of the green light emitted from the laser element 30-2 and the center of the entrance approximately overlap. The emission port of the laser element 30-3 faces the incidence port of the optical waveguide 51-3. In the y and z directions, the optical axis of the red light emitted from laser element 30-3 and the center of the incidence port are approximately overlapped.

As shown in FIG. 2, the blue light, the green light, and the red light emitted from the laser elements 30-1, 30-2, and 30-3 are incident on the optical waveguides 51-1, 51-2, and 51-3, respectively, and then propagate through the optical waveguides, respectively. The blue light and the green light propagating through the optical waveguides 51-1 and 51-2 are combined at the junction position 57-1. The combined blue light and green light and the red light propagating through the optical waveguide 51-3 are combined at the junction position 57-2. The RGB light combined at the junction position 57-2 propagates through optical waveguide 51-4, reaches the emission surface 50C, and is emitted from the emission surface 50C.

In order to prevent light leakage from the optical waveguides 51-1, 51-2, and 51-3, it is preferable that the optical waveguides 51-1, 51-2, and 51-3 are each connected to the optical waveguide 51-4 with a curvature radius equal to or greater than a predetermined radius of curvature.

The optical waveguides 51-1, 51-2, 51-3, and 51-4 may be made of a lithium niobate film (LiNbO₃). In this case, for example, a sapphire substrate, a Si substrate, or a thermally oxidized silicon substrate can be used as the optical waveguide substrate 40.

The bonding surfaces 22 (22-1, 22-2, 22-3) of the individual subcarriers 20-1, 20-2, 20-3 and the bonding surface 40A (40A-1, 40A-2, 40A-3) of the optical waveguide substrate 40 are joined via multiple metal films 70 (70-1, 70-2, 70-3).

The metal film 70 is disposed between the bonding surfaces 22-1, 22-2, 22-3 of the individual subcarriers 20-1, 20-2, 20-3 and the bonding surfaces 40A (40A-1, 40A-2, 40A-3) of the optical waveguide substrate 40 that correspond to the bonding surfaces 22-1, 22-2, 22-3, respectively, and are disposed apart from each other.

The metal film 70 is not a continuously formed film, but is arranged only on the spaced-apart bonding surfaces 40A-1, 40A-2, and 40A-3, and is an electrically and spatially separated film, which can suppress the occurrence of capacitive coupling and crosstalk.

For convenience, the metal film 70 shown in FIG. 3 is drawn as a three-layer structure, reflecting the manufacturing process of the metal film 70 (or the bonding process between the subcarrier and the optical waveguide substrate). Also, when explaining the metal film 70, each of the three layers may be explained.

That is, for the sake of convenience, the metal film 70 is depicted as consisting of three layers: a first metal film 74 (74-1, 74-2, 74-3) disposed on each of the bonding surfaces 22-1, 22-2, 22-3 of the individual subcarriers 20-1, 20-2, 20-3; a second metal film 72 (72-1, 72-2, 72-3) disposed on a plurality of bonding surfaces 40A-1, 40A-2, 40A-3 of the optical waveguide substrate 40 that correspond to the bonding surfaces 22-1, 22-2, 22-3, and that are spaced apart from each other; and a eutectic layer 73 disposed between the first metal film 74 and the second metal film 72. A preferred eutectic bonding for the eutectic layer 73 is Au-Sn bonding.

In actual bonding, if the first metal film and the second metal film are sufficiently thin, an alloy layer (eutectic layer) is formed, and the first metal film and the second metal film do not remain. On the other hand, if either the first metal film or the second metal film is thick, only the surface side of the thick metal film may become eutectic, leaving the part on the subcarrier side or the optical waveguide substrate side, and the other metal film may become eutectic in its entirety, but it may be difficult to distinguish them as clear layers (distinguishing the interface).

In this way, in actual bonding, the film structure of the metal film 70 will differ depending on the conditions of the manufacturing process of the metal film 70, and the figure is a conceptual depiction of the characteristic aspects of the film structure.

For example, a structure in which one or both of the first metal film 74 and the second metal film 72 remain relatively, or a structure in which the entire first metal film 74 and the entire second metal film 72 are alloyed to form a eutectic layer may be obtained.

The second metal film 72 disposed on the bonding surfaces 40A-1, 40A-2, and 40A-3 is preferably made of Sn or an alloy containing Sn, such as Sn-Ag-Cu (SAC).

The first metal film 74 disposed on the bonding surfaces 22-1, 22-2, and 22-3 is preferably a metal capable of forming a eutectic with Sn, and may be, for example, one selected from the group consisting of Au, Si, Al, Ni, Pb, Zn, and Pt, or an alloy thereof, but is more preferably made of Au or an alloy containing Au.

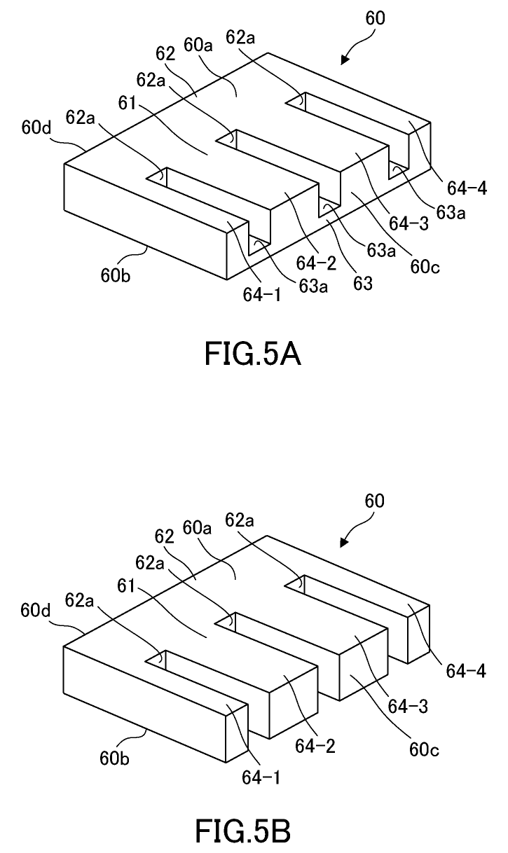

As shown in FIG. 5A, the heat sink 60 includes a comb-shaped fin portion 61 that contacts both side surfaces of each of the plurality of subcarriers 20-1, 20-2, and 20-3, a rear wall portion 62, and a bottom portion 63 having an upper surface 63a that contacts the bottom surface 20b of each of the subcarriers 20-1, 20-2, and 20-3.

Alternatively, as shown in FIG. 5B, the heat sink 60 may not have a bottom portion 63, that is, it may include a comb-shaped fin portion 61 that contacts both side surfaces of each of the subcarriers 20-1, 20-2, and 20-3, and a rear wall portion 62.

The heat sink 60 is integrally formed from a ceramic material or a metal material. Examples of the ceramic material that can be used to form the heat sink 60 include AlN, SiC, and the like. Moreover, examples of the metal material that can be used to form the heat sink 60 include Cu, Al, Au, and Ag.

The fin portion 61 has multiple fins 64 (64-1, 64-2, 64-3, 64-4). The fin 64-1 contacts the side surface 23-1a of the subcarrier 20-1. The fin 64-2 contacts the side surface 23-1b of the subcarrier 20-1 and the side surface 23-2a of the subcarrier 20-2. The fin 64-3 contacts the side surface 23-2b of the subcarrier 20-2 and the side surface 23-3a of the subcarrier 20-3. The fin 64-4 contacts the side surface 23-3b of the subcarrier 20-3.

In other words, the fin portion 61 is configured to sandwich the laser elements 30-1, 30-2, and 30-3 from the side surfaces 23. When the number of laser elements 30 is greater than three, the fin portion 61 only needs to have a number of fins 64 sufficient to sandwich all of the side surfaces 23 of the subcarrier 20 of each laser element 30.

By attaching the heat sink 60 to the subcarrier 20 in this manner, heat generated in the laser elements 30 can be efficiently dissipated from the side surface 23 of the subcarrier 20 closest to the laser elements 30. In other words, the heat sink 60 makes it possible to realize a laser assembly 100 with high heat dissipation capacity, low heat dissipation resistance, and short heat dissipation distance.

As shown in FIG. 1, gaps are provided between the front surface 62a of the rear wall portion 62 and the end surfaces 24-1, 24-2, and 24-3 of the multiple subcarriers 20-1, 20-2, and 20-3. In this way, by contacting the heat sink 60 with the side surfaces 23 of each of the subcarriers 20-1, 20-2, and 20-3 and leaving a space behind the heat sink 60, the expansion and contraction directions of the subcarriers 20-1, 20-2, and 20-3 can be limited to only directions parallel to the optical axis of the emitted light from the laser elements 30-1, 30-2, and 30-3.

Further, if gaps are generated between the side surfaces 23 or the bottom surface 20b of the subcarriers 20-1, 20-2, and 20-3 and the fin portion 61 or the bottom portion 63 of the heat sink 60 due to manufacturing errors of the heat sink 60 or mounting errors of the subcarriers 20-1, 20-2, and 20-3 to the optical waveguide substrate 40, it is desirable to fill these gaps with a bonding material.

The above-mentioned bonding material must be a material selected from among the materials that do not melt the metal film 70. For example, silver paste or AuSn solder, which have high thermal conductivity, can be suitably used.

Alternatively, the above-mentioned bonding material may be a getter material capable of adsorbing organic matter and moisture in the laser module, which will be described later. A getter material that can be suitably used as the bonding material is, for example, an epoxy-based material such as a glycidyl ether of a phenol-formaldehyde polymer (Phenol-Formaldehyde Polymer Glycidyl Ether). Alternatively, the getter material used as the bonding material may be a metal such as Al, Ti, V, Cr, Mn, Fe, Co, Ni, Zr, Nb, Hf, Ta, Pt, and Au, or an alloy thereof.

By using a getter material as a bonding material, in addition to improving the dissipation of heat generated by the laser element 30, it is possible to adsorb organic matter and moisture that inhibit the light emission of the laser element 30, thereby realizing a highly reliable laser assembly 100.

As shown in FIG. 3, the heat sink 60 is mechanically separated from the optical waveguide substrate 40 and the optical waveguide layer 50. In other words, there is a sufficient distance between the front surface 60c of the heat sink 60 and the bonding surface 40A of the optical waveguide substrate 40 and the incidence surface 50A of the optical waveguide layer 50 so that stress is not applied to the optical waveguide substrate 40 and the optical waveguide layer 50 when the subcarrier 20 and the heat sink 60 thermally expand and contract.

The laser assembly 100 is provided so that the bottom surface 60b facing the upper surface 60a of the heat sink 60 and the bottom surface 43 facing the main surface (upper surface) 41 of the optical waveguide substrate 40 are positioned on approximately the same plane S, regardless of the presence or absence of the bottom portion 63. If the heat sink 60 is configured not to have the bottom portion 63, the bottom surface 60b does not exist directly below the subcarrier 20, so that it is desirable to fill the gap between the bottom surface 20b of the subcarrier 20 and the approximately same plane S with a bonding material such as silver paste.

Here, the approximately same plane S allows for a slight misalignment between the bottom surface 60b and the bottom surface 43. Specifically, a misalignment of 20 μm or less is allowed with respect to the thickness of the optical waveguide substrate 40 along the z direction, but the smaller the misalignment, the better, with 10 μm or less being more preferable, and 5 μm or less being even more preferable.

As in the illustrated laser assembly 100, if the bottom surface 60b of the heat sink 60 and the bottom surface 43 of the optical waveguide substrate 40 are formed to be on approximately the same plane S, both the heat sink 60 and the optical waveguide substrate 40 can be bonded, for example, to one plane of the package. This makes it possible for the laser assembly 100 to efficiently dissipate heat generated by the operation of the laser element 30 from both the bottom surface 60b of the heat sink 60 and the bottom surface 43 of the optical waveguide substrate 40, in comparison with a case in which the bottom surface of the heat sink and the bottom surface of the optical waveguide substrate are not on approximately the same plane and thus bonding can carried out only at one of the bottom surfaces.

In addition, as in the illustrated laser assembly 100, by providing the bottom surface 60b of the heat sink 60 and the bottom surface 43 of the optical waveguide substrate 40 on approximately the same plane S, when bonding the laser assembly 100 to one plane of the package, both the bottom surface 60b of the heat sink 60 and the bottom surface 43 of the optical waveguide substrate 40 can be bonded to the one plane of the package, so that the bonding strength can be kept high and a laser assembly 100 with excellent impact resistance can be realized.

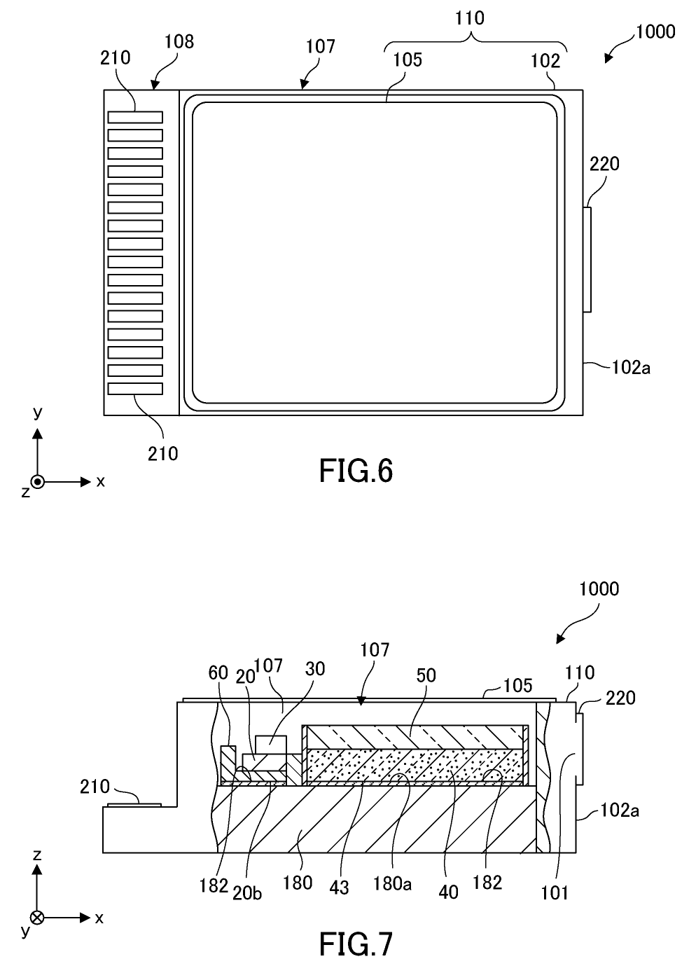

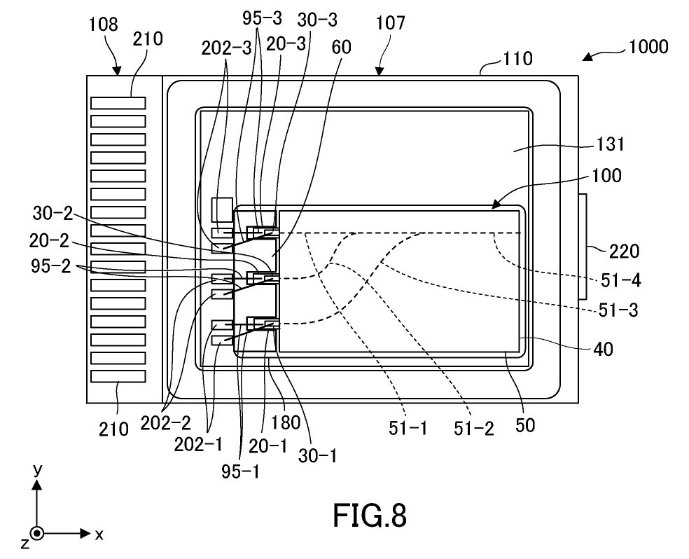

FIG. 6 is a schematic plan view of the laser module of this embodiment. FIG. 7 is a diagram showing a cross section of a laser assembly arranged inside a part of the laser module shown in FIG. 6 cut in the X-Z plane. FIG. 8 is a plan view of the laser module with the cover removed.

In the laser module 1000, the laser assembly 100 according to the above embodiment is mounted and housed on the upper surface 180a of the base 180 in the package 110.

The laser assembly 100 housed in the package 110 is preferably bonded to the package so that the bottom surface 60b of the heat sink 60 and the bottom surface 43 of the optical waveguide substrate 40 are positioned on approximately the same plane. In the laser assembly 100, the subcarrier 20 and the optical waveguide substrate 40 are bonded by metal eutectic bonding, so the occurrence of misalignment during the heating process is significantly suppressed as compared to a configuration in which they are bonded by adhesive.

The package 110 may house therein other known components in addition to the laser assembly according to the above embodiment. For example, a photodetector (PD) can be housed inside the package 110.

When the laser module 1000 house therein a PD, it is possible to check the fluctuation in the optical output of the laser element by observing the current flowing through the PD. It is also possible to control the drive current of the laser element so that the output is constant by monitoring the current flowing through the PD.

The package 110 is provided with a main body 102 having a cavity structure and a cover 105 that covers the main body 102. The main body 102 has a bottom on which the members housed therein are placed, and sidewalls 102a that are arranged to surround these members from their sides.

Of the side walls of the storage portion 107, a side wall portion 102a in the vicinity of the emission portion of the laser light emitted from the laser module 1000 is formed with a light-transmitting window (opening) 101 through which the laser light emitted from the laser element 30 can optically pass.

The opening 101 is formed with its center approximately at a position where it intersects with the optical axis of the laser light emitted from the side wall 102a. The opening 101 is tightly covered by a glass plate 220 from the outside of the side wall 102a. In other words, the storage portion 107 is hermetically sealed by the glass plate 220 in addition to the cover 105. Here, the glass plate 220 is used for hermetic sealing, but it is not limited to a glass plate as long as it is a material through which the laser light can pass. An anti-reflection film (not shown) may be provided on both plate surfaces of the glass plate 220.

The electrode portion 108 is disposed on the front side of the storage portion 107 in the x direction, that is, rearward in the x direction. The upper surface of the electrode portion 108 is located lower than the upper surface of the storage portion 107. The bottom surface of the electrode portion 108 is located at approximately the same height as the bottom surface of the storage portion 107. A plurality of external electrode pads 210 are provided on the upper surface of the electrode portion 108 to be spaced apart from each other in the y direction.

The bottom surface 60b of the heat sink 60 and the bottom surface 43 of the optical waveguide substrate 40 may be joined to the upper surface 180a (one inner surface) of the base 180 via an adhesive layer 182. The adhesive layer 182 is made of a material in which a filler is mixed into a resin in order to improve thermal conductivity. An example of the resin that constitutes the adhesive layer 182 is epoxy resin. Copper powder, aluminum powder, alumina powder, etc. can be used as a filler to improve the thermal conductivity of the resin.

In order to maintain a certain level of thermal conductivity, the adhesive layer 182 preferably has a thermal conductivity of 0.5 W/m·K or more, more preferably a thermal conductivity of 1 W/m·K or more, and even more preferably a thermal conductivity of 4 W/m·K or more.

In other words, the multiple subcarriers 20-1, 20-2, 20-3 are thermally coupled to the package 110 via the heat sink 60 by bonding the bottom surface 60b of the heat sink 60 to the base 180 in the package 110.

In this way, by bonding both the heat sink 60 and the optical waveguide substrate 40 of the laser assembly to the upper surface 180a of the base 180 in the package 110, the heat generated by the operation of the laser element 30 can be efficiently dissipated from both the bottom surface 60b of the heat sink 60 and the bottom surface 43 of the optical waveguide substrate 40 toward the base 180. Furthermore, by bonding both the bottom surface 60b of the heat sink 60 and the bottom surface 43 of the optical waveguide substrate 40 with an adhesive layer made of a resin mixed with a filler, heat can be efficiently propagated from both the bottom surface 60b of the heat sink 60 and the bottom surface 43 of the optical waveguide substrate 40 toward the base 180.

Alternatively, the heat sink 60 may be integrated with the base 180 of the package 110. By forming the heat sink 60 in the package 110 in advance in this way, the number of steps in the process of manufacturing the laser module 1000 can be reduced.

As shown in FIG. 8, a plurality of internal electrode pads 202 (202-1, 202-2, 202-3) are provided at intervals in the y direction on the bottom wall portion 131 located between the base 180 below the subcarrier 20 and the external electrode pad 210 in the x direction.

The laser element 30 and the subcarrier 20 are connected to the internal electrode pads 202 corresponding to each laser element 30 by wires 95 using a method such as wire bonding. For example, the laser element 30-1 and the subcarrier 20-1 are connected to the two internal electrode pads 202-1 by wires 95-1. The laser element 30-2 and the subcarrier 20-2 are connected to the two internal electrode pads 202-2 by wires 95-2. The laser element 30-3 and the subcarrier 20-3 are connected to the two internal electrode pads 202-3 by wires 95-3.

The internal electrode pads 202-1, 202-2, and 202-3 are connected to different external electrode pads 210. As described above, the external electrode pads 210 electrically connected to the internal electrode pads 202-1, 202-2, and 202-3 are electrically connected to a power source (not shown). That is, in the laser assembly 100, the laser element 30 and the power source (not shown) are connected by the wires 95, the internal electrode pads 202-1, 202-2, and 202-3, and the external electrode pads 210. When power is supplied from the power source (not shown) to the external electrode pads 210 corresponding to the internal electrode pads 202-1, 202-2, and 202-3, the blue light, the green light, and the red light are emitted from the laser elements 30-1, 30-2, and 30-3, respectively.

Next, a laser module according to a second embodiment of the present disclosure will be described with reference to the drawings. Here, it should be noted that the same names or symbols are used for configurations similar to those in the first embodiment, and thus descriptions thereof will be omitted as appropriate. Furthermore, descriptions of operations similar to those in the first embodiment will also be omitted as appropriate.

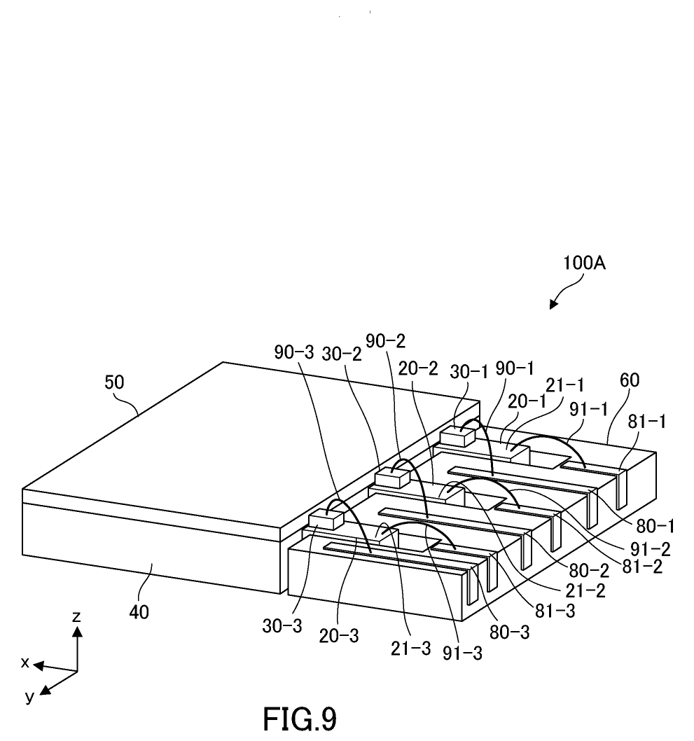

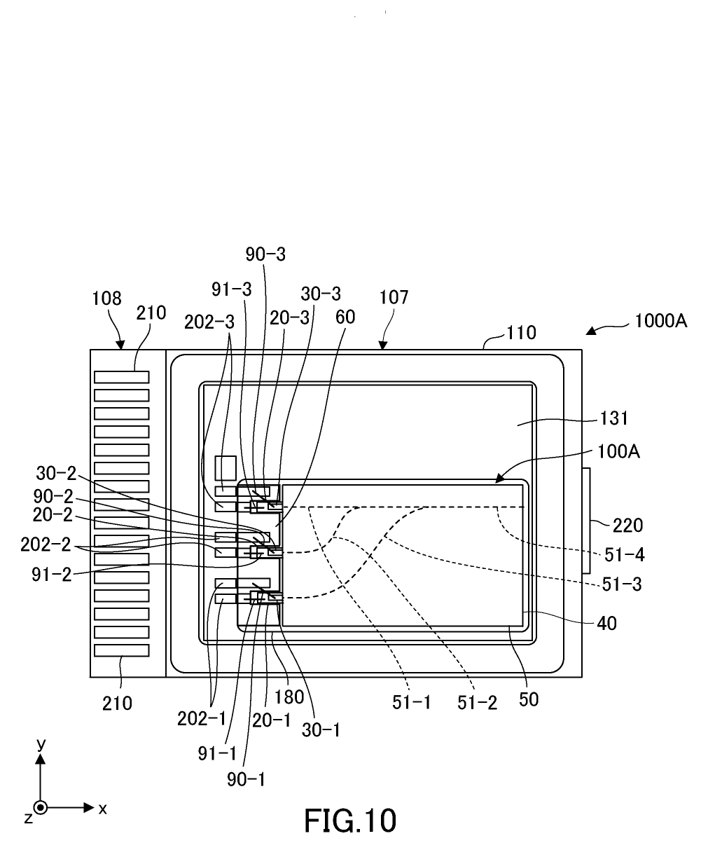

FIG. 9 is a schematic perspective view of a laser assembly 100A provided in a laser module of the second embodiment. FIG. 10 is a plan view of the laser module with the cover removed.

In the laser assembly 100A of this embodiment, electrode patterns 80, 81 for electrically connecting the laser element 30 and the subcarrier 20 to the internal electrode pads 202 are formed on the upper surface 60a and rear surface 60d of the heat sink 60 located immediately adjacent to the laser element 30 and the subcarrier 20, respectively, via an insulating layer (not shown).

The laser elements 30-1, 30-2, 30-3 and the electrode patterns 80 (80-1,80-2, 80-3) are connected by wires 90 (90-1, 90-2, 90-3) using a method such as wire bonding. The subcarriers 20-1, 20-2, 20-3 and the electrode patterns 81 (81-1, 81-2, 81-3) are connected by wires 91 (91-1, 91-2, 91-3) using a method such as wire bonding.

The electrode patterns 80, 81 on the heat sink 60 and the internal electrode pads 202 can be electrically connected by, for example, soldering. If the heat sink 60 is integrated with the base 180 of the package 110, a configuration may be provided in which wiring is provided to connect the electrode patterns 80, 81 and the internal electrode pads 202.

Therefore, in this embodiment, as compared to a configuration in which the laser element 30 and the subcarrier 20 are directly connected to the internal electrode pads 202 by wires, the laser element 30 and the subcarrier 20 can be electrically connected to the internal electrode pads 202 by using short wires 90, 91, so that a laser module 1000A with excellent electrical characteristics and high reliability can be realized.

Next, the XR glasses according to the third embodiment of the present disclosure will be described with reference to the drawings. Here, it should be noted that the same names or symbols are used for configurations similar to those of the first or second embodiment, and thus descriptions thereof will be omitted as appropriate. Also, descriptions of operations similar to those of the first or second embodiment will be omitted as appropriate.

The XR glasses according to this embodiment are equipped with the laser module according to the first or second embodiment described above. The XR glasses (eyeglasses) are glasses-type terminals, and XR is a general term for virtual reality (VR), augmented reality (AR), and mixed reality.

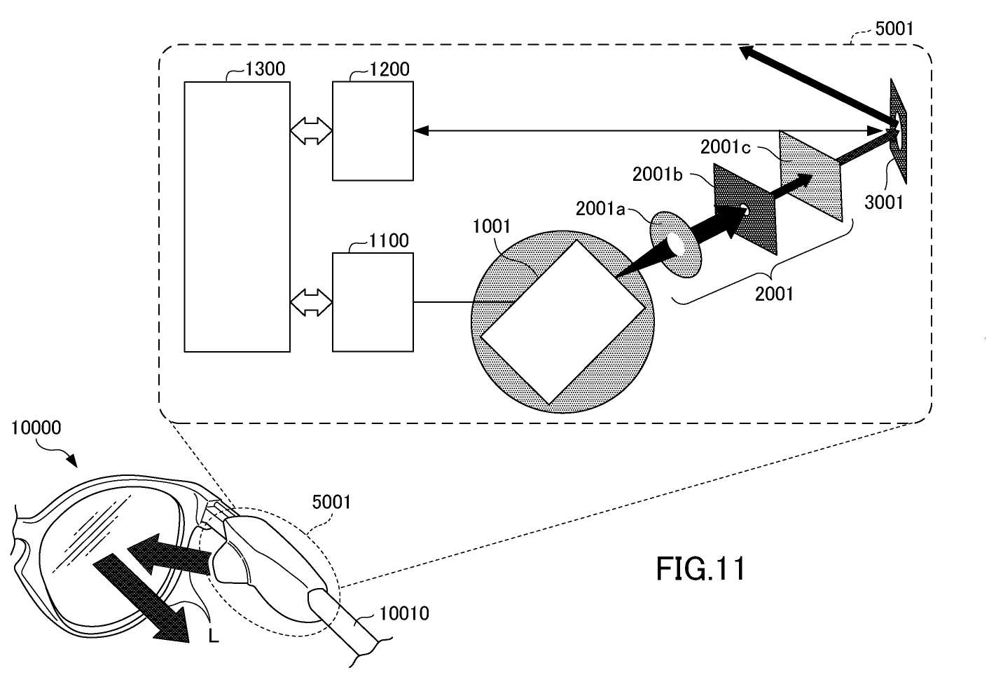

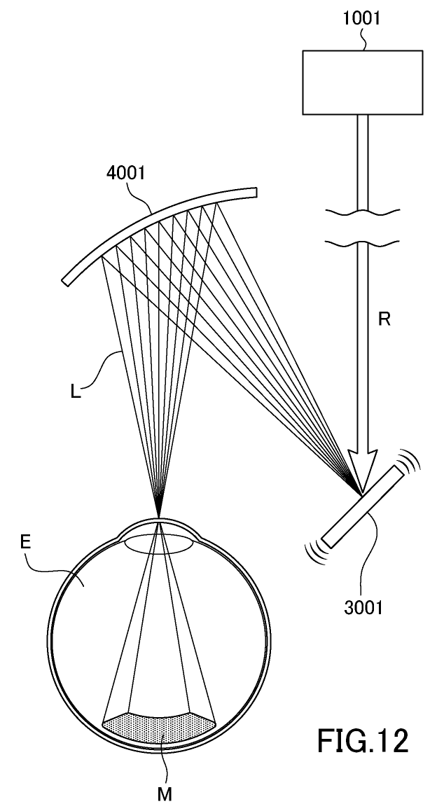

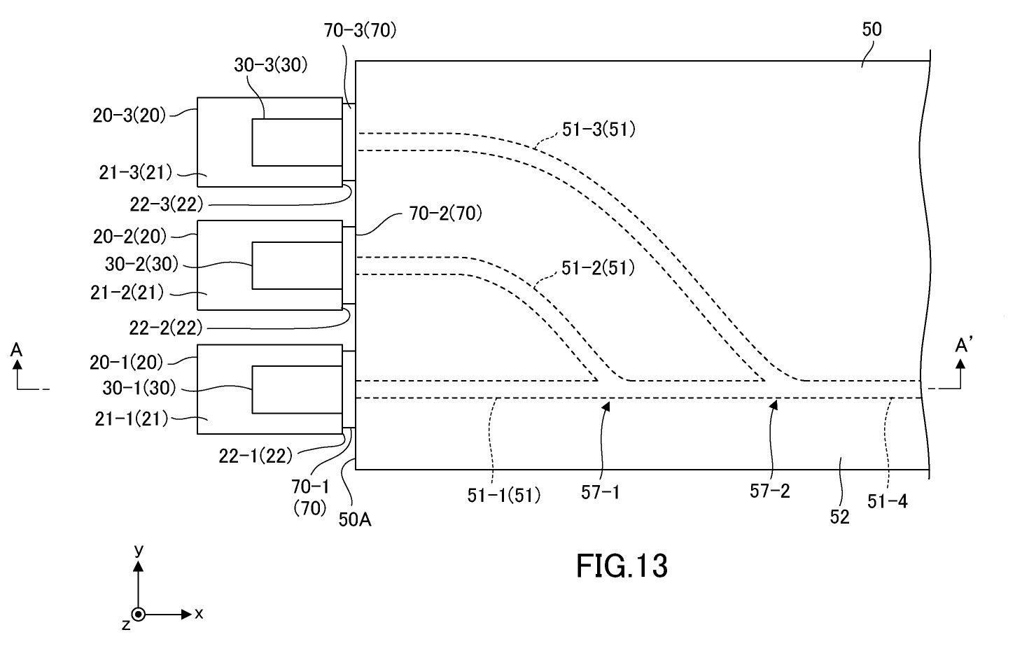

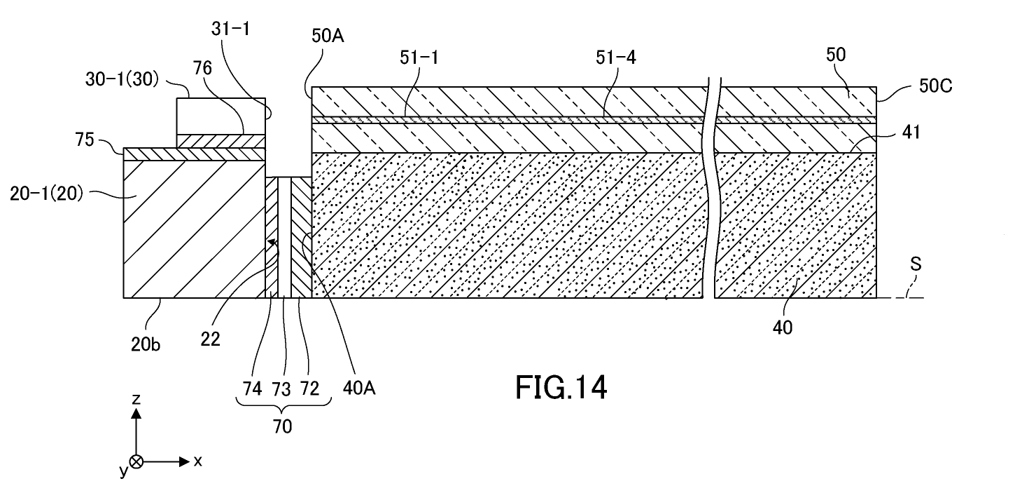

FIG. 11 shows a conceptual diagram for explaining the XR glasses according to this embodiment. The XR glasses 10000 shown in FIG. 11 have a laser module 1001 mounted on an optical engine 5001 provided on a frame 10010. The symbol L is image display light.

In FIG. 11, the laser module 1001, the optical scanning mirror 3001, and the optical system 2001 connecting the laser module 1001 and the optical scanning mirror 3001 provided in the XR glasses 10000 are collectively referred to as the optical engine 5001 in this specification. The laser module 1001 may be any of the laser modules according to the above embodiments.

The light source in the laser module 1001 may be, for example, a laser module having RGB laser elements 30-1, 30-2, and 30-3, and a near-infrared laser element.

As shown in FIG. 12, the laser light emitted from the laser module 1001 attached to the eyeglass frame is reflected by the optical scanning mirror 3001, and the reflected light is reflected by the mirror 4001 that reflects it toward the human eyeball E, enters the human eyeball E, and an image (video) can be projected directly onto the retina M.

By providing an eye tracking mechanism, an image is projected directly onto the retina while performing eye tracking. As the eye tracking mechanism, a known eye tracking mechanism may be used.

The optical scanning mirror 3001 may be, for example, a MEMS mirror that scans the laser light emitted from the laser module 1001. To project a 2D image, it is preferable to use a two-axis MEMS mirror that vibrates to reflect the laser light at different angles in the horizontal direction (X direction) and vertical direction (Y direction).

The optical system 2001 that optically processes the laser light emitted from the laser module 1001 has a collimator lens 2001a, a slit 2001b, and an ND filter 2001c. This optical system is one example, and other configurations may be used.

The optical engine 5001 has a laser driver 1100, an optical scanning mirror driver 1200, and a video controller 1300 that controls these drivers.

### Appendix

One aspect of the present disclosure is the laser module, in which a gap is provided between the heat sink and an end surface of each of the plurality of laser element bases on the side opposite to the bonding surface with the optical waveguide substrate.

One aspect of the present disclosure is the laser module, in which a plurality of electrode patterns are formed on the heat sink.

One aspect of the present disclosure is the laser module, in which a bonding material fills a gap between the plurality of laser element bases and the heat sink.

One aspect of the present disclosure is the laser module, in which the bonding material is silver paste or AuSn solder.

One aspect of the present disclosure is the laser module, in which the bonding material is a getter material that adsorbs organic matter and moisture.

One aspect of the present disclosure is the laser module, in which the heat sink is integrated with the package.

One aspect of the present disclosure is the laser module, in which the heat sink is mechanically separated from the optical waveguide substrate and the optical waveguide layer.

One aspect of the present disclosure is the laser module, in which the bottom surface of the heat sink and the bottom surface of the optical waveguide substrate are located on the same plane.

One aspect of the present disclosure is the laser module, in which the heat sink is formed of a ceramic material or a metal material.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

### DESCRIPTION OF REFERENCE NUMERALS AND SIGNS

20 Subcarrier (laser element base)

21 Main surface

22 Bonding surface

24 End surface

30 Laser element

40 Optical waveguide substrate

40A Bonding surface

41 Main surface

50 Optical waveguide layer

51 Optical waveguide

60 Heat sink

80, 81 Electrode pattern

100, 100A Laser assembly

110 Package

1000, 1000A, 1001 Laser module

3001 Optical scanning mirror

5001 Optical engine

10000 XR glasses

What is claimed is:

1. A laser module comprising:
a plurality of laser element bases;
a plurality of laser elements mounted on the respective main surfaces of the plurality of laser element bases;
an optical waveguide substrate having an optical waveguide layer on its main surface, the optical waveguide layer having an optical waveguide for guiding laser light respectively emitted from the plurality of laser elements;
a heat sink having comb-shaped fin portion in contact with both side surfaces of the plurality of laser element bases; and
a package that houses the plurality of laser element bases on which the plurality of laser elements are mounted, the optical waveguide substrate on which the optical waveguide layer is provided, and the heat sink,
wherein the plurality of laser element bases are thermally coupled to the package via the heat sink.

2. The laser module according to claim 1,
wherein a gap is provided between the end surface of each of the plurality of laser element bases on the side opposite to the bonding surface with the optical waveguide substrate and the heat sink.

3. The laser module according to claim 1,
wherein a plurality of electrode patterns are formed on the heat sink.

4. The laser module according to claim 3,
wherein a part of the plurality of electrode patterns is connected to the respective laser elements by wires.

5. The laser module according to claim 3,
wherein each of the laser element bases and each of the laser elements are connected to each other via a respective metal film, and wherein a part of the plurality of electrode patterns is connected to the respective laser element bases by wires.

6. The laser module according to claim 1,
wherein a bonding material fills a gap between the plurality of laser element bases and the heat sink.

7. The laser module according to claim 6,
wherein the bonding material is silver paste or AuSn solder.

8. The laser module according to claim 6,
wherein the bonding material is a getter material that adsorbs organic matter and moisture.

9. The laser module according to claim 8,
wherein the getter material contains phenol-formaldehyde polymer glycidyl ether.

10. The laser module according to claim 1,
wherein the heat sink is integrated with the package.

11. The laser module according to claim 1,
wherein the heat sink is mechanically separated from the optical waveguide substrate and the optical waveguide layer.

12. The laser module according to claim 1,
wherein the bottom surface of the heat sink and the bottom surface of the optical waveguide substrate are located on the same plane.

13. The laser module according to claim 1,
wherein the plurality of laser elements include:
a laser element that emits the red laser light having a peak wavelength of 630 nm or more and 830 nm or less;
a laser element that emits the green laser light having a peak wavelength of 500 nm or more and 550 nm or less; and
a laser element that emits the blue laser light having a peak wavelength of 380 nm or more and 500 nm or less.

14. The laser module according to claim 1,
wherein the optical waveguide layer is a PLC (Planar Lightwave Circuit) formed of a glass material.

15. The laser module according to claim 1,
wherein the optical waveguide layer is a PLC formed of a lithium niobate film.

16. The laser module according to claim 1,
wherein the optical waveguide substrate is formed of silicon.

17. The laser module according to claim 15,
wherein the optical waveguide substrate is formed of sapphire, silicon, or thermally oxidized silicon.

18. The laser module according to claim 1,
wherein the heat sink is formed from a ceramic material or a metal material.

19. An optical engine comprising:
a laser module according to claim 1; and
an optical scanning mirror that scans the light emitted from the laser module.

20. XR glasses comprising the optical engine according to claim 19.
